(19) United States
(12) Patent Application Publication
(10) Pub. No.: US 2026/0190674 A1
(43) Pub. Date: Jul. 2, 2026

(54) DISPLAY DEVICE

(71) Applicant: LG Display Co., Ltd., Seoul (KR)

(72) Inventors: UngGi Lee, Paju-si (KR); HongJae Shin, Seoul (KR); YongHo Kim, Seoul (KR); SuCheol Lee, Seoul (KR)

(73) Assignee: LG Display Co., Ltd., Seoul (KR)

(21) Appl. No.: 19/436,473

(22) Filed: Dec. 30, 2025

(30) Foreign Application Priority Data
Dec. 31, 2024 (KR) 10-2024-0202686

(51) Int. Cl. H10K 59/124; H10K 59/122; H10K 59/126; H10K 59/131; H10K 59/80

(52) U.S. Cl. CPC H10K 59/124; H10K 59/122; H10K 59/126; H10K 59/131; H10K 59/80521

(57) ABSTRACT

A display device according to an exemplary embodiment of the present disclosure may include a substrate including a display area and a non-display area outside the display area, an insulating layer and a planarization layer disposed above the substrate and extending from the display area to the non-display area, at least one trench disposed in the non-display area and formed by removing at least one of the insulating layer and the planarization layer, a bank disposed on the planarization layer and extending to the non-display area, an organic layer disposed on the bank, a cathode extending to the organic layer, and a protective layer disposed on the cathode, and a gate-in-panel (GIP) circuit part disposed in the non-display area on a first side, and positioned inside the trench, thereby minimizing a moisture permeation effect and improving the reliability of the display device.

### CROSS-REFERENCE TO RELATED APPLICATIONS

This application claims the priority of Korean Patent Application No. 10-2024-0202686 filed on Dec. 31, 2024, in the Korean Intellectual Property Office, the disclosure of which is incorporated herein by reference.

### BACKGROUND

### Technical Field

The present disclosure relates to a display device, and more particularly, to a display device capable of preventing moisture permeation.

### Discussion of the Related Art

In the current information era, the field of display devices that visually display electrical information signals is rapidly developing, and research is being conducted to develop performances such as thinning, weight reduction, and low power consumption for various display devices.

Representative display devices include a liquid crystal display (LCD), an electro-wetting display (EWD), and an organic light emitting display (OLED).

Among them, an electroluminescent display device including an organic light emitting display device is a self-emitting display device and does not require a separate light source unlike a liquid crystal display device, and thus may be manufactured to have a light weight and a small thickness. In addition, the electroluminescent display devices are advantageous due to low voltage driving, offering benefits in power consumption. They also provide superior color reproduction, response speed, viewing angle, and contrast ratio, which makes them suitable for various applications.

In an electroluminescent display device, a certain bezel distance is essential to prevent moisture permeation and ensure reliability, but the shadow area resulting from the gap between the mask and the substrate during cathode and organic layer deposition acts as a major factor that limits bezel reduction. In addition, if the bezel is reduced, there is a high possibility of corrosion in the gate-in-panel (GIP) wiring due to moisture permeation, which may compromise reliability.

### SUMMARY

Accordingly, embodiments of the present disclosure are directed to a display device that substantially obviates one or more of the problems due to limitations and disadvantages of the related art.

An aspect of the present disclosure is to provide a display device which blocks moisture and oxygen while reducing a bezel width.

Another aspect of the present disclosure is to provide a display device capable of preventing corrosion of wiring of a GIP circuit part.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described, a display device may comprise a substrate including a display area and a non-display area outside the display area, an insulating layer and a planarization layer disposed on the substrate and extending from the display area to the non-display area, at least one trench disposed in the non-display area and formed by removing a partial area of at least one of the insulating layer and the planarization layer, a bank disposed on the planarization layer and extending to the non-display area, an organic layer disposed on the bank, a cathode disposed on the organic layer and extending to the at least one trench, and a protective layer disposed on the cathode, and a gate-in-panel (GIP) circuit part disposed in the non-display area on a first side and positioned inside the at least one trench.

A display device according to another exemplary embodiment of the present disclosure may include a substrate including a display area and a non-display area outside the display area, at l east one trench disposed in the non-display area, a first low potential power line disposed in the trench, a cathode disposed in the display area so as to extend to the trench and coupled to the first low potential power line, a gate-in-panel circuit part disposed in the non-display area on a first side and positioned inside the trench and a ground wiring disposed outside the trench in the non-display area on the first side and a third side.

Other detailed matters of the embodiments are included in the detailed description and the drawings.

According to the present disclosure, a trench is formed in a shadow area caused by the use of a deposition mask, thereby allowing the bezel width to be reduced and enhancing the reliability of the moisture resistance.

According to the present disclosure, the GIP circuit part is disposed inside the trench, and the GIP circuit part is encapsulated by a cathode, thereby minimizing the effect of moisture permeation and enhancing the reliability of the display device.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles.

FIG. 1 is a plan view of a display device according to a first embodiment of the present disclosure.

FIG. 2 is a cross-sectional view of a sub-pixel of the display device of FIG. 1.

FIG. 3 is a view illustrating a part of a cross-section of the display device of FIG. 1 according to Ia-Ia′.

FIG. 4 is a view illustrating a part of a cross-section of the display device of FIG. 1 according to Ib-Ib′.

FIG. 5 is a view illustrating a part of a cross-section of the display device of FIG. 1 according to Ic-Ic′.

FIG. 6 is a plan view of a display device according to a second embodiment of the present disclosure.

FIG. 7 is a cross-sectional view taken along a line IIa-IIa′ of the display device of FIG. 6.

FIG. 8 is a cross-sectional view taken along the line IIb-IIb′ of the display device of FIG. 6.

FIG. 9 is a cross-sectional view of a display device according to a third embodiment of the present disclosure.

FIG. 10 is a cross-sectional view of a display device according to a fourth embodiment of the present disclosure.

FIG. 11 is a cross-sectional view of a display device according to a fifth embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

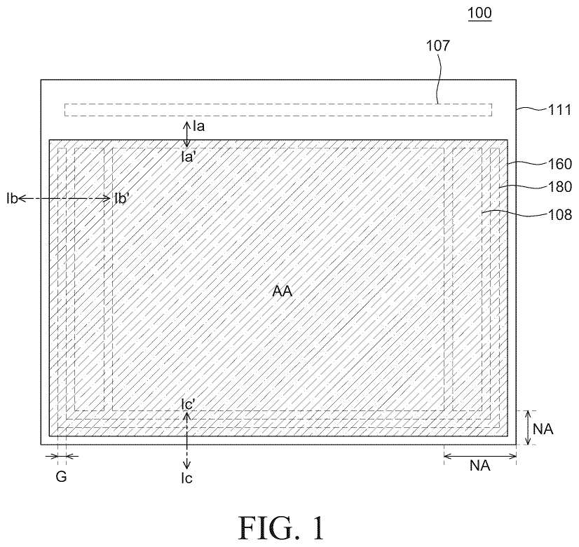

FIG. 1 is a plan view of a display device according to a first embodiment of the present disclosure.

Referring to FIG. 1, a display device 100 according to the first embodiment of the present disclosure may include a substrate 111, an encapsulation substrate 160, and pad parts 107 and 108.

The display device 100 is a device for displaying an image to a user.

In the display device 100, a display element for displaying images, a driving element for driving the display element, and wirings for transmitting various signals to the display element and the driving element may be disposed. The display element may be differently defined depending on the type of the display device 100, and for example, when the display device 100 is an organic light emitting display device, the display element may be an organic light emitting element including an anode, an organic emission layer, and a cathode. For example, when the display device 100 is a liquid crystal display device, the display element may be a liquid crystal display element.

Hereinafter, even though it is assumed that the display device 100 is the organic light emitting display device, the display device 100 is not limited to the organic light emitting display device.

The display device 100 may include a display area AA and a non-display area NA.

The display area AA is an area in which images are displayed in the display device 100.

In the display area AA, a plurality of sub-pixels constituting a plurality of pixels and a circuit for driving the plurality of sub-pixels may be disposed. The plurality of sub-pixels is minimum units constituting the display area AA, and a display element may be disposed in each of the plurality of sub-pixels, and the plurality of sub-pixels may constitute a pixel. For example, the organic light emitting element including the anode, the organic emission layer, and the cathode may be disposed in each of the plurality of sub-pixels, but it is not limited thereto. Further, a circuit for driving the plurality of sub-pixels may include a driving element, a wiring, and the like. For example, the circuit may be formed of a thin film transistor, a storage capacitor, a gate line, a data line, or the like, but is not limited thereto.

The non-display area NA is an area where no image is displayed.

FIG. 1 illustrates that the non-display area NA encloses the display area AA having a rectangular shape. However, the shapes and arrangements of the display area AA and the non-display area NA are not limited to the example illustrated in FIG. 1.

In other words, the display area AA and the non-display area NA may have shapes suitable for the design of an electronic device equipped with the display device 100. For example, an exemplary shape of the display area AA may be a pentagon, a hexagon, a circle, or an oval.

In the non-display area NA, various wirings and circuits for driving the organic light emitting element of the display area AA may be disposed. For example, in the non-display area NA, link lines for transmitting signals to the plurality of sub-pixels and circuits of the display area AA, driving ICs such as gate driver ICs and data driver ICs or pad parts 107 and 108 may be disposed, but are not limited thereto.

The display device 100 may include various additional elements for generating various signals or driving pixels in the display area AA. The additional elements for driving the pixels may include an inverter circuit, a multiplexer, an electrostatic discharge (ESD) circuit, and the like. The display device 100 may also include additional elements related to functions other than pixel driving. For example, the display device 100 may include additional elements that provide a touch sensing function, a user authentication function (e.g., fingerprint recognition), a multi-level pressure sensing function, a tactile feedback function, and the like. The above-mentioned additional elements may be located in the non-display area NA and/or an external circuit connected to the connection interface.

The pad parts 107 and 108 may be disposed to receive a signal from the outside.

The pad parts 107 and 108 may be disposed in the non-display area NA of the display device 100 to be electrically connected to various wirings and printed circuit boards disposed in the display area AA.

For example, the pad parts 107 and 108 may function to transmit a signal to each of the gate line and the data line, and include a gate pad part 108 to transmit a gate signal to the gate line and a data pad part 107 to transmit a data signal to the data line, but are not limited thereto.

The gate pad part 108 may be disposed on at least one side of the display device 100, for example, in the non-display area NA on the first side of the display device 100, but is not limited thereto. For example, the first side may mean one of left and right sides of the display device 100 adjacent to the upper and lower sides.

The data pad part 107 may be disposed on another side of the display device 100, for example, in the non-display area NA on the second side of the display device 100, but is not limited thereto. For example, the second side may mean an upper side of the display device 100. However, the present disclosure is not limited thereto, and any one of the first, second, third, and fourth sides of the non-display area NA may be referred to for each side of the non-display area NA.

For example, the data pad part 107 may be electrically connected to a data driver to supply a data voltage to a plurality of data lines. The data driver may receive image data from the timing controller and supply a data voltage to the plurality of data lines to drive the plurality of data lines. The data driver may be implemented by including one or more source driver integrated circuits.

For example, each source driver integrated circuit may include a shift register, a latch circuit, a digital to analog converter (DAC), an output buffer, and the like. The data driver may further include one or more analog to digital converters (ADCs), in some cases.

Meanwhile, the gate driver may drive a plurality of gate lines by outputting a scan signal to the plurality of gate lines. For example, the gate driver may sequentially drive the plurality of gate lines by sequentially supplying scan signals to the plurality of gate lines. The gate driver may sequentially supply an on voltage or an off voltage scan signal to the plurality of gate lines under the control of the timing controller.

The gate driver may include a plurality of gate driving circuits. Here, the plurality of gate driving circuits may correspond to the plurality of gate lines, respectively.

For example, each gate driving circuit may include a shift register, a level shifter, and the like.

Each gate driving circuit may be implemented in a gate-in-panel (GIP) type and embedded in the display device 100. For example, each gate driving circuit may be directly disposed on the gate pad part 108, and in this case, the gate pad part 108 may be referred to as a GIP circuit part.

Meanwhile, in the display device 100 according to the first exemplary embodiment of the present disclosure, the trench 180 may be provided in the non-display area NA to secure reliability such as prevention of moisture permeation.

The trench 180 may be disposed to surround the display area AA excluding the second side, for example, the upper side, but is not limited thereto.

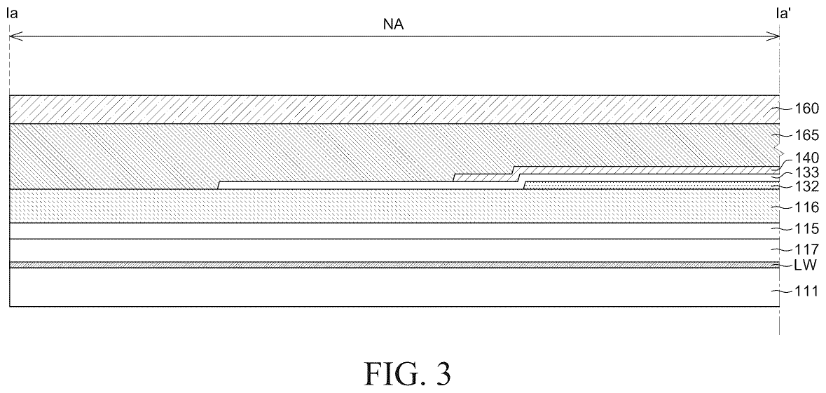

Further, in the display device 100 according to the first exemplary embodiment of the present disclosure, the GIP circuit part (or gate pad part) 108 is disposed inside the trench 180 (in other words, inward of the trench 180) so as to be spaced apart from the trench 180 at a predetermined interval G so that the moisture permeation effect on the GIP circuit part 108 may be minimized, which will be described in detail with reference to FIGS. 3 to 5.

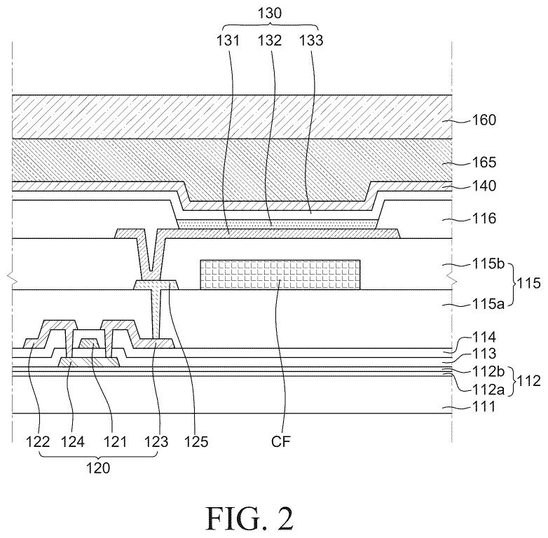

FIG. 2 is a cross-sectional view of a sub-pixel of the display device of FIG. 1.

FIG. 3 is a view illustrating a part of a cross-section of the display device of FIG. 1 according to Ia-Ia′.

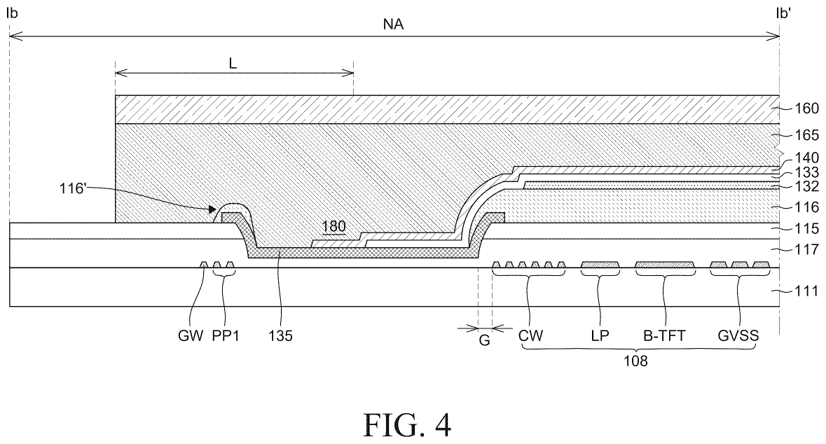

FIG. 4 is a view illustrating a part of a cross-section of the display device of FIG. 1 according to Ib-Ib′.

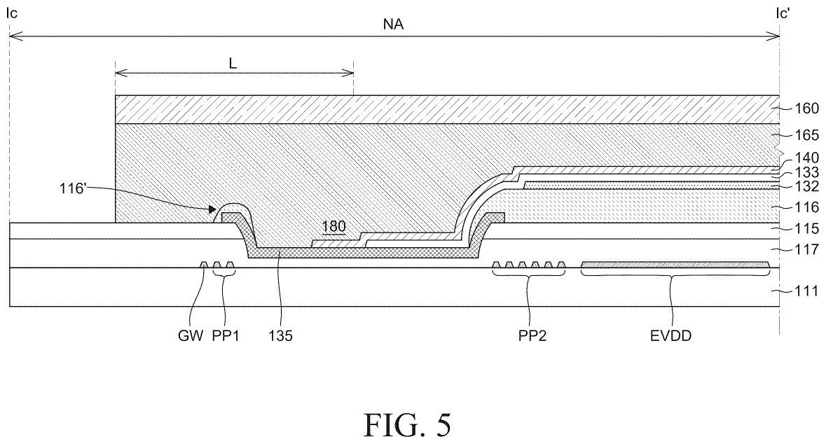

FIG. 5 is a view illustrating a part of a cross-section of the display device of FIG. 1 according to Ic-Ic′.

FIG. 3 shows a part of the non-display area NA on the second side of the display device 100 of FIG. 1, and FIG. 4 shows a part of the non-display area NA on the first side of the display device 100 of FIG. 1. In addition, FIG. 5 illustrates a part of the non-display area NA on the third side of the display device 100 of FIG. 1.

For example, the first side may refer to the left side of the display device 100, the second side may refer to the upper side of the display device 100, and the third side may refer to the lower side located on the opposite side to the upper side, but it is not limited thereto.

In FIG. 4, for the convenience of description, the GIP circuit part 108 in the non-display area NA is schematically illustrated.

In FIGS. 3 to 5, for the convenience of description, at least some of a buffer layer 112, a gate insulating layer 113, and an interlayer insulating layer 114 are illustrated as insulating layers 117.

Referring to FIGS. 2 to 5, in the display device 100 of the first embodiment of the present disclosure, the driving element 120 may be disposed over the substrate 111.

Further, the planarization layer 115 may be disposed over the driving element 120.

Further, the light emitting element 130 electrically connected to the driving element 120 may be disposed over the planarization layer 115, and the protective layer 140 may be disposed over the light emitting element 130.

The adhesive layer 165 and the encapsulation substrate 160 may be sequentially disposed over the protective layer 140. However, the display device 100 according to the first embodiment of the present disclosure is not limited to this laminated structure.

Meanwhile, the trench 180 may be provided at an edge of the non-display area NA between the substrate 111 and the encapsulation substrate 160.

The substrate 111 may be a glass or plastic substrate. In the case of a plastic substrate, a polyimide-based or polycarbonate-based material may be used to have flexibility. In particular, polyimide is a material that can be applied to a high-temperature process and can be coated, so it is widely used as a plastic substrate.

A buffer layer 112 may be disposed on the substrate 111.

Meanwhile, although not illustrated, a light shielding layer may be disposed on the substrate 111 to block light introduced from a lower portion of the substrate 111.

A light shielding layer may be disposed on the substrate 111 at a position where the active layer 124 is to be formed. In particular, it is preferable that the size of the light shielding layer is slightly larger so as to completely cover the active layer 124.

The buffer layer 112 may be disposed on the entire surface of the substrate 111 on which the light shielding layer is formed.

The buffer layer 112 is a layer for protecting various electrodes and wirings from impurities such as alkali ions discharged from the substrate 111 or the underlying layers. The buffer layer 112 may have a multilayer structure including a first buffer layer 112a and a second buffer layer 112b, but is not limited thereto. For example, the buffer layer 112 may be made of silicon oxide (SiOx), silicon nitride (SiNx), or a multi-layer thereof.

The buffer layer 112 may delay diffusion of moisture and/or oxygen permeating the substrate 111. In addition, the buffer layer 112 may include a multi-buffer and/or an active buffer. The active buffer protects the active layer 124 made of the semiconductor of the driving element 120 and may perform a function of blocking various types of defects introduced from the substrate 111. The active buffer may be formed of amorphous silicon (a-Si) or the like.

Meanwhile, in the non-display area NA, various wirings and circuits for driving the light emitting element 130 of the display area AA may be disposed. For example, in the non-display area NA, link lines for transmitting signals to the plurality of sub-pixels and circuits of the display area AA, driving ICs such as gate driver ICs and data driver ICs or pad parts 107 and 108 may be disposed, but are not limited thereto.

For example, the ground wiring GW may be disposed over the substrate 111 in the non-display area NA.

The ground wiring GW may be disposed at an outermost edge of the non-display area NA excluding the second side.

The ground wiring GW may be disposed adjacent to the edge of the encapsulation substrate 160.

A first light blocking pattern PP1 may be disposed inside the ground wiring GW. The first light blocking pattern PP1 may be disposed between the ground wiring GW and the trench 180.

The link line LW may be disposed above the substrate 111 in the non-display area NA on the second side.

In the non-display area NA on the left and right sides, the GIP circuit part 108 may be disposed inside the trench 180. A detailed description thereof will be provided later with reference to FIG. 4.

The GIP circuit part 108 may include a control signal clock line CW, a logic unit LP, a buffer TFT unit B-TFT, and a power line GVSS, but is not limited thereto.

For example, the control signal clock line CW, the logic unit LP, the buffer TFT unit B-TFT, and the power line GVSS may be sequentially disposed from the trench 180, but the present disclosure is not limited thereto.

In this case, the control signal clock line CW, the logic unit LP, the buffer TFT unit B-TFT, and the power line GVSS may be formed of a material constituting the light shielding layer and/or the driving element 120 of the display area AA, but are not limited thereto.

In addition, in the non-display area NA on the third side and/or the fourth side in which the GIP circuit part 108 and the data pad part 107 do not exist, a second light blocking pattern PP2 and a high potential power line EVDD may be disposed inside or on an inner side of the trench 180.

For example, the second light blocking pattern PP2 and the high potential power line EVDD may be sequentially disposed from the trench 180, but the present disclosure is not limited thereto.

The second light blocking pattern PP2 and the high potential power line EVDD may be made of a material constituting the light shielding layer and/or the driving element 120 of the display area AA, but the present disclosure is not limited thereto.

The driving element 120 may include an active layer 124, a gate insulating layer 113, a gate electrode 121, an interlayer insulating layer 114, a source electrode 122, and a drain electrode 123. Further, the driving element 120 may be electrically connected to the light emitting element 130 through a connection electrode 125 to transmit a current or a signal to the light emitting element 130. In addition to the illustrated top gate structure, the driving element 120 may be applied in various ways, such as a bottom gate structure in which the gate electrode is located below the active layer and a coplanar structure in which the gate electrode, the source electrode, and the drain electrode are disposed on the same plane.

The active layer 124 may be positioned on the buffer layer 112. The active layer 124 may be made of polysilicon (p-Si), and in this case, a predetermined region may be doped with impurities. Further, the active layer 124 may be made of amorphous silicon (a-Si) and may be made of an organic semiconductor material such as pentacene. Further, the active layer 124 may be formed of an oxide semiconductor.

The gate insulating layer 113 may be positioned on the active layer 124. For example, the gate insulating layer 113 may be formed of an insulating inorganic material such as silicon oxide (SiOx) or silicon nitride (SiNx), or an insulating organic material.

The gate electrode 121 may be positioned on the gate insulating layer 113. For example, the gate electrode 121 may be made of various conductive materials, such as magnesium (Mg), aluminum (Al), nickel (Ni), chromium (Cr), molybdenum (Mo), tungsten (W), gold (Au), or an alloy thereof.

The interlayer insulating layer 114 may be positioned on the gate electrode 121. For example, the interlayer insulating layer 114 may be formed of an insulating material such as silicon oxide (SiOx) or silicon nitride (SiNx), or an insulating organic material.

A contact hole through which the source and drain regions are exposed may be formed by selective removal of the gate insulating layer 113 and the interlayer insulating layer 114. The source electrode 122 and the drain electrode 123 may be formed on the interlayer insulating layer 114 in a single layer or a multi-layered structure using an electrode material.

If necessary, an additional protective layer made of an inorganic insulating material may be formed to cover the source electrode 122 and the drain electrode 123.

Meanwhile, at least some of the buffer layer 112, the gate insulating layer 113, and the interlayer insulating layer 114, i.e., the insulating layer 117, may extend to the non-display area NA from the display area AA.

The planarization layer 115 may be disposed over the driving element 120 configured as described above.

The planarization layer 115 may have a multilayer structure including at least two layers. For example, referring to FIG. 2, the planarization layer 115 may include a first planarization layer 115a and a second planarization layer 115b, but is not limited thereto.

For example, the first planarization layer 115a is disposed to cover the driving element 120 and may be disposed to expose a part of the source electrode 122 or the drain electrode 123 of the driving element 120.

The planarization layer 115 may extend to the non-display area NA from the display area AA.

The planarization layer 115 may be an overcoat layer, but is not limited thereto.

The connection electrode 125 for electrically connecting the driving element 120 and the light emitting element 130 may be disposed on the first planarization layer 115a. In addition, although not illustrated in FIG. 2, various metal layers serving as wires/electrodes such as data lines and signal lines may be disposed on the first planarization layer 115a. In addition, the color filter CF can be disposed on the first planarization layer 115a, and is not limited thereto, and the color filter CF can be omitted depending on the type of the organic light emitting element 130. The color filter CF of each sub-pixel can have any one of red, green, and blue colors. In addition, in the case of a sub-pixel in which white is implemented, the color filter CF may not be disposed. The arrangement of red, green and blue can be formed in various ways.

Further, the second planarization layer 115b may be disposed on the first planarization layer 115a and the connection electrode 125. The planarization layer 115 of the first exemplary embodiment of the present disclosure is composed of two layers due to an increase in various signal lines as the display device 100 has a high resolution. Accordingly, it is difficult to dispose all wirings on one layer while securing a minimum gap, so an additional layer is formed. The addition of the additional layer (i.e., the second planarization layer 115b) may provide room for wiring arrangement, which may make it easier to design wiring/electrode arrangement. In addition, when a dielectric material is used as the planarization layer 115 configured as a multilayer, it may be used for forming capacitance between metal layers.

The second planarization layer 115b may be formed to expose a part of the connection electrode 125. Further, the drain electrode 123 of the driving element 120 and the anode 131 of the light emitting element 130 may be electrically connected by the connection electrode 125.

In this case, the light emitting element 130 may be configured such that the anode 131, a plurality of organic layers 132, and the cathode 133 are sequentially disposed. That is, the light emitting element 130 may include the anode 131 disposed on the planarization layer 115, the organic layer 132 disposed on the anode 131, and the cathode 133 disposed on the organic layer 132.

The display device 100 may be implemented in a top emission type or a bottom emission type. In the top emission type, a reflective layer made of an opaque conductive material having high reflectivity, for example, silver (Ag), aluminum (Al), gold (Au), molybdenum (Mo), tungsten (W), chromium (Cr), or an alloy thereof, may be added under the anode 131 so that light emitted from the organic layer 132 is reflected by the anode 131 and directed upward, that is, in the direction toward the cathode 133 at the top. Conversely, in the case of the bottom emission type, the anode 131 may be made of only a transparent conductive material such as indium tin oxide (ITO), indium zinc oxide (IZO), indium gallium zinc oxide (IGZO). Hereinafter, the description will be made on the assumption that the display device 100 of the present disclosure is a bottom emission type. However, the present disclosure is not limited thereto.

A bank 116 may be formed over the planarization layer 115 in a region other than an emission region. That is, the bank 116 has a bank hole exposing the anode 131 corresponding to the emission area. The bank 116 may be made of an inorganic insulating material such as silicon nitride (SiNx) or silicon oxide (SiOx), or an organic insulating material such as BCB, acrylic resin, or imide resin.

The bank 116 may extend to the non-display area NA.

The organic layer 132 may be disposed on the anode 131 exposed by the bank 116. The organic layer 132 may include an emission layer, an electron injection layer, an electron transport layer, a hole transport layer, a hole injection layer, and the like.

The organic layer 132 may extend to the non-display area NA.

The cathode 133 may be disposed on the organic layer 132.

In the case of the top emission type, the cathode 133 may include a transparent conductive material. For example, the cathode 133 may be formed of indium tin oxide (ITO), indium zinc oxide (IZO), indium gallium zinc oxide (IGZO), or the like. In the case of the bottom emission type, the cathode 133 may include any one of a group formed of a metal material such as gold (Au), silver (Ag), aluminum (Al), molybdenum (Mo), magnesium (Mg), palladium (Pd), copper (Cu) or an alloy thereof. Alternatively, the cathode 133 may be configured by laminating a layer made of a transparent conductive material such as indium tin oxide (ITO), indium zinc oxide (IZO), indium gallium zinc oxide (IGZO), and a layer made of a metal material such as gold (Au), silver (Ag) aluminum (Al), molybdenum (Mo), magnesium (Mg), palladium (Pd), copper (Cu), or an alloy thereof, but is not limited thereto.

The cathode 133 may extend to the non-display area NA.

Although not illustrated, a capping layer may be disposed on the cathode 133. The capping layer may be formed of a material having a high refractive index and a high light absorption rate to reduce diffused reflection of external light.

The protective layer 140 may be disposed over the light emitting element 130 configured as described above.

The protective layer 140 may be an inorganic layer, and in this case, may be made of silicon oxide (SiOx), silicon nitride (SiNx), or a multi-layer thereof.

The protective layer 140 may extend to the non-display area NA.

The adhesive layer 165 and the encapsulation substrate 160 may be disposed over the protective layer 140.

However, the present disclosure is not limited thereto, and an encapsulation structure of a multilayer structure composed of a sealing member and a reinforcing substrate may be disposed over the protective layer 140.

The adhesive layer 165 may be disposed between the protective layer 140 and the encapsulation substrate 160.

For example, the adhesive layer 165 may serve to delay lateral moisture permeation.

For example, the adhesive layer 165 may further include a desiccant such as a getter in addition to isobutyl rubber resin. The desiccant may include calcium oxide.

The desiccant may be particles having hygroscopicity and absorb moisture and oxygen from the outside to minimize the penetration of moisture and oxygen into the display area AA.

The encapsulation substrate 160 may be disposed on the adhesive layer 165.

The encapsulation substrate 160, together with the adhesive layer 165, may protect the light emitting element 130 from external moisture, oxygen, impact, and the like.

For example, the encapsulation substrate 160 may serve to prevent moisture permeation from the front.

For example, the encapsulation substrate 160 may be made of steel use stainless (SUS) or Invar, but is not limited thereto. At this time, Invar is one of the alloys consisting of nickel and iron, and has a very low coefficient of thermal expansion and is relatively stable against temperature changes.

In the non-display area NA, at least some layers of the buffer layer 112, the gate insulating layer 113, and the interlayer insulating layer 114, that is, the insulating layer 117 may extend.

Further, the planarization layer 115 may extend to the non-display area NA.

For example, the insulating layer 117 and the planarization layer 115 extending to the non-display area NA may extend to an end of the substrate 111, but are not limited thereto.

Meanwhile, in the display device 100, a minimum bezel distance is required to ensure reliability, such as preventing moisture permeation, and while there is an increasing demand for slimming the non-display area NA excluding the display area AA in which an image is displayed to meet the demand for a slimmer display device 100, a shadow area is generated due to the gap between the mask and the substrate during deposition of the cathode 133 and the organic layer 132, which limits the reduction of the bezel.

Accordingly, in the first embodiment of the present disclosure, the trench 180 is disposed in the shadow area in the non-display area NA. That is, in the first embodiment of the present disclosure, the trench 180 may delay the rate of moisture penetration toward the side of the display device 100. In addition, by converting the conventional shadow area into the reliability bezel area L in this manner, the bezel width may be reduced. The reliability bezel area L may be defined from an end portion of the encapsulation substrate 160 to an end portion of the cathode 133.

The trench 180 may be formed in the non-display area NA on the left, right, and lower sides of the display device 100 excluding the upper side on which the data pad part 107 is disposed (see FIG. 1), but is not limited thereto. In this case, for example, the trench 180 may be formed by removing partial areas or at least one of the insulating layer 117 and the planarization layer 115 in the non-display area NA through laser melting. Accordingly, the reliability bezel area L may be expanded, and the bezel width may be reduced by the length of the added reliability bezel area L. In this case, for example, the trench 180 may expose at least some of the buffer layer 112, the gate insulating layer 113, and the interlayer insulating layer 114.

For example, the trench 180 may have a predetermined width to prevent deterioration in moisture permeation performance regardless of a position where the cathode 133 is formed in consideration of a process error and a margin.

Meanwhile, a low potential power line 135 may be disposed in the trench 180.

For example, the low potential power line 135 may be disposed to cover the inside of the trench 180. That is, the low potential power line 135 may be disposed to cover upper and side surfaces of the insulating layer 117 and the planarization layer 115 exposed by the trench 180.

For example, the low potential power line 135 may be disposed along the trench 180 in the non-display area NA on the left, right, and lower sides of the display device 100, but is not limited thereto.

The low potential power line 135 may include an inner portion and an outer portion disposed on an inclined side surface of the trench 180. For example, in the non-display area NA excluding the second side, the bank 116 may extend to the non-display area NA to cover an inner portion of the low potential power line 135. Here, the inner portion of the low potential power line 135 may be defined as a side portion adjacent to the display area AA, and may be opposite to a side portion adjacent to an outer portion of the non-display area NA. In this case, the inner portion of the low potential power line 135 may be disposed on the inner sidewall of the trench 180 with a predetermined taper. For example, the sidewall of the trench 180 and the side portion of the low potential power line 135 may have a gentle taper of about 30 degrees or less. Such a gentle taper allows the thickness of the cathode 133 deposited on top to be secured at 1,000 Å or more.

The outer bank 116′ may cover the outer portion of the low potential power line 135 in an island shape or in a form of an island. Meanwhile, the bank 116 and the outer bank 116′ may be separated and disposed on both sides with respect to the trench 180, and a part of a top surface of the low potential power line 135 may be exposed without being covered by the outer bank 116′.

The outer bank 116′ may be disposed to be spaced apart from an edge of the adhesive layer 165 and the encapsulation substrate 160 by a predetermined distance. That is, in the first embodiment of the present disclosure, the outer bank 116′ is formed to cover the low potential power line 135 and the tapered portion of the planarization layer 115, and removed from the remaining areas. Accordingly, the water transfer velocity (WTV) may be suppressed. For example, it can be seen that when the bank in the outer region is deleted, the rate of moisture penetration is reduced by about 10%.

In contrast, in the non-display area NA on the second side, the bank 116 may extend to the non-display area NA along the planarization layer 115, but is not limited thereto.

Meanwhile, in the non-display area NA, the organic layer 132 may be disposed on the bank 116.

The organic layer 132 extends to the non-display area NA, and its edge may be disposed inside compared to the edge of the bank 116, but is not limited thereto.

In the non-display area NA, the cathode 133 may be disposed on the organic layer 132.

In this case, the cathode 133 may extend into the trench 180 to cover a part of the exposed top surface or upper surface of the low potential power line 135, but is not limited thereto.

For example, the cathode 133 may extend into the trench 180 to cover the bank 116 and the organic layer 132 within the trench 180.

The cathode 133 may be in contact with the exposed top surface or upper surface of the low potential power line 135, and thus may receive low potential power from the low potential power line 135. The cathode 133 may be disposed in the display area AA so as to extend to the trench 180 and coupled to the low potential power line 135.

In addition, the protective layer 140 may extend into the trench 180 to cover the cathode 133, but is not limited thereto. The protective layer 140 may be disposed on the cathode 133. For example, in the non-display area NA excluding the second side, the protective layer 140 may be disposed to surround the cathode 133. On the other hand, in the non-display area NA on the second side, the protective layer 140 may cover a part of the upper surface of the cathode 133.

For example, the protective layer 140 may be made of an inorganic insulating material.

The protective layer 140 may delay moisture permeation from above and suppress defects caused by pressure marks or foreign substances.

The protective layer 140 may be made of silicon oxide (SiOx), silicon nitride (SiNx), or a multi-layered structure thereof to delay moisture permeation, but is not limited thereto.

The encapsulation substrate 160 may be disposed over the protective layer 140 with an adhesive layer 165 interposed therebetween.

Meanwhile, the display device 100 according to the first embodiment of the present disclosure configured as described above is characterized in that the GIP circuit part 108 is disposed inside the trench 180.

That is, when the GIP circuit part is located under the trench or at the edge of the encapsulation substrate as in the conventional art, driving failures due to wiring corrosion frequently occur during moisture permeation. For example, in the conventional design, the GIP circuit part was disposed approximately 0.2 mm from the edge of the encapsulation substrate, so moisture could corrode the GIP circuit part and cause driving malfunctions.

The first embodiment of the present disclosure is characterized in that the trench 180 is disposed at the edge of the non-display area NA, and the GIP circuit part 108 is disposed inside the trench 180 so as to be spaced apart from the trench 180 at a predetermined interval G. Accordingly, for example, a distance of 1.5 mm or more can be ensured between the GIP circuit part 108 and the edge of the encapsulation substrate 160.

In addition, in the first embodiment of the present disclosure, the main wiring (i.e., the high potential power line EVDD) may be rearranged into the inside of the trench 180.

In the first embodiment of the present disclosure, the cathode 133 may extend into the trench 180 to seal the GIP circuit part 108. That is, in the conventional art, moisture penetrates into the bank or the organic film material of the planarization layer, thereby damaging not only the GIP circuit part but also the light emitting element. However, the cathode 133 in the present disclosure may extend into the trench 180, adjoin the low potential power line 135, and seal the entire GIP circuit part 108 and the display area AA, thereby preventing the penetration of moisture or oxygen.

Accordingly, the present disclosure may minimize the effect of moisture permeation, thereby dramatically improving the stability and durability of the GIP circuit part 108. Accordingly, it is possible to improve the reliability of the display device 100.

Meanwhile, in the present disclosure, a trench may be additionally disposed inside the trench, which will be described in detail with reference to the drawings.

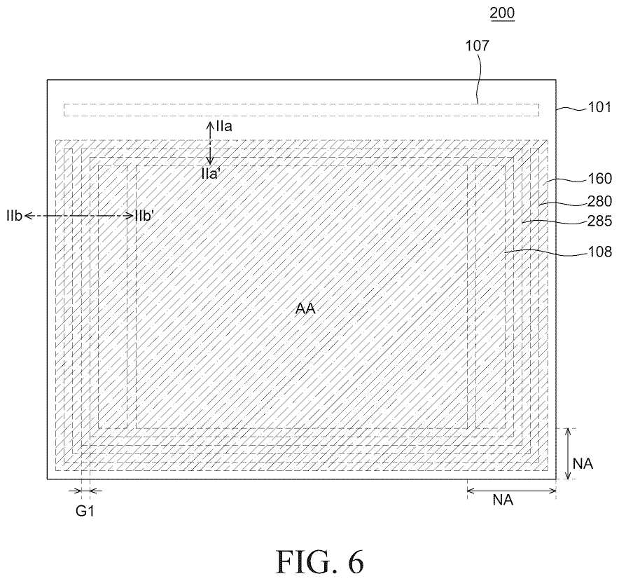

FIG. 6 is a plan view of a display device according to a second embodiment of the present disclosure.

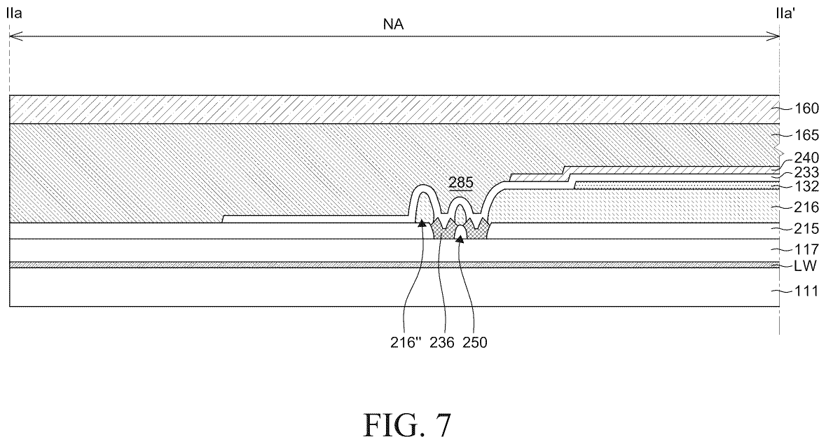

FIG. 7 is a cross-sectional view taken along a line IIa-IIa′ of the display device of FIG. 6.

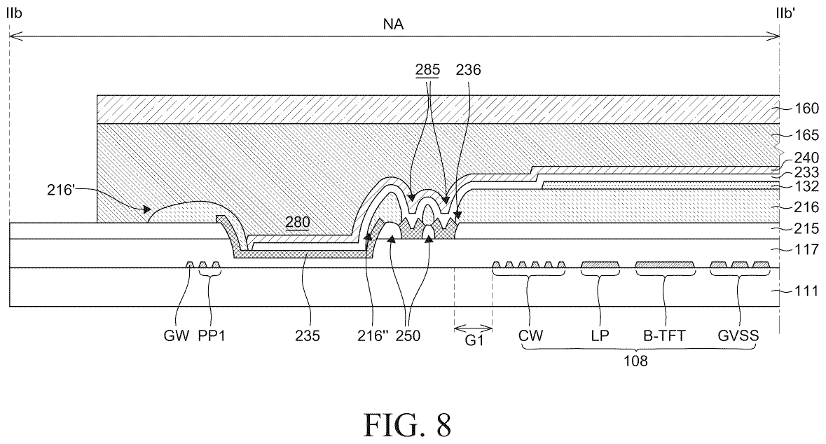

FIG. 8 is a cross-sectional view taken along the line IIb-IIb′ of the display device of FIG. 6.

The second embodiment of FIGS. 6 to 8 has a different trench 280 and 285 configuration than the first embodiment of FIGS. 1 to 5 described above, and the other configuration is substantially the same, so that a redundant description will be omitted. The same components will be denoted by the same reference numerals. Hereinafter, description of the same reference numerals may refer to FIG. 1 through FIG. 5.

FIG. 7 illustrates a part of the non-display area NA on the second side of the display device 200 of FIG. 6, and FIG. 8 illustrates a part of the non-display area NA on the first side of the display device 200 of FIG. 6.

In FIG. 8, for the convenience of description, the GIP circuit part 108 in the non-display area NA is schematically illustrated.

Further, in FIGS. 7 and 8, for the convenience of description, at least some of the buffer layer, the gate insulating layer, and the interlayer insulating layer are illustrated as the insulating layer 117.

Referring to FIGS. 6 to 8, in the display device 200 according to the second exemplary embodiment of the present disclosure, a planarization layer 215 may be disposed over the substrate 111.

The ground wiring GW may be disposed over the substrate 111 in the non-display area NA excluding the second side. The ground wiring GW may be disposed outside the trenches 280 and 285 in the non-display area NA on the first side and the third side.

A first light blocking pattern PP1 may be disposed inside the ground wiring GW.

The link line LW may be disposed above the substrate 111 in the non-display area NA on the second side.

In the non-display area NA on the left and right sides of the second exemplary embodiment of the present disclosure, the GIP circuit part 108 may be disposed inside the trenches 280 and 285.

The GIP circuit part 108 may include a control signal clock line CW, a logic unit LP, a buffer TFT unit B-TFT, and a power line GVSS, but is not limited thereto.

A light emitting element (130 in FIG. 2) electrically connected to the driving element (120 in FIG. 2) may be disposed over the planarization layer 215 of the display area AA.

A bank 216 may be formed over the planarization layer 215 in the remaining area excluding the emission area.

The insulating layer 117, the planarization layer 215, and the bank 216 may extend to the non-display area NA.

For example, the insulating layer 117 and the planarization layer 215 extending to the non-display area NA may extend to an end of the substrate 111, but are not limited thereto.

Meanwhile, in the second exemplary embodiment of the present disclosure, a plurality of trenches 280 and 285 are disposed in the shadow area in the non-display area NA.

The trenches 280 and 285 may include a first trench 280 and one or a plurality of second trenches 285.

The first trench 280 may be disposed in the non-display area NA, for example, may be formed in the non-display area NA on the left, right, and lower sides of the display device 200, excluding the upper side on which the data pad part 107 is disposed (see FIG. 6), but is not limited thereto. In this case, for example, the first trench 280 may be formed by removing partial areas of the insulating layer 117 and the planarization layer 215 in the non-display area NA. Accordingly, for example, the first trench 280 may expose at least some of the buffer layer, the gate insulating layer, and the interlayer insulating layer.

The second trench 285 may be positioned inside the first trench 280, and formed over the four sides of the display device 200, that is, the non-display area NA on upper, left, right, and lower sides (see FIG. 6), but is not limited thereto. In this case, for example, the second trench 285 may be formed by removing a portion of the planarization layer 215 of the non-display area NA. Further, for example, the second trench 285 may expose at least some of the buffer layer, the gate insulating layer, and the interlayer insulating layer.

The plurality of second trenches 285 may be disposed.

The first trench 280 may have a width greater than that of each of the second trench 285. For example, the first trench 280 may be referred to as an OC (overcoat) hole, and the second trench 285 may be referred to as a bar trench.

For example, a plurality of dams 250 may be disposed between the second trenches 285.

For example, the plurality of dams 250 may be disposed between the first trench 280 and the second trench 285, and between the second trenches 285, but is not limited thereto.

The dam 250 may be configured as the planarization layer 215, but is not limited thereto.

The dam 250 may have a height lower than that of the surrounding planarization layer 215, but is not limited thereto.

Meanwhile, a first low potential power line 235 may be disposed in the first trench 280.

The first low potential power line 235 may be disposed to cover the inside of the first trench 280. That is, the first low potential power line 235 may be disposed to cover upper and side surfaces of the insulating layer 117 and the planarization layer 215 exposed by the first trench 280. The first low potential power line 235 may be disposed to cover a top surface of the insulating layer 117, and a part of a top surface and a side surface of the planarization layer 215 exposed by the first trench 280.

In this case, the first low potential power line 235 may be disposed along the first trench 280 in the non-display area NA on the left, right, and lower sides of the display device 200, but is not limited thereto.

In addition, a second low potential power line 236 may be disposed in the second trench 285 and coupled to the cathode 233.

The second low potential power line 236 may be disposed to cover the inside of the second trench 285. That is, the second low potential power line 236 may be disposed to cover a top surface of the insulating layer 117 and the side surface and a part of the upper surface of the dam 250 exposed by the second trench 285.

In this case, the second low potential power line 236 may be disposed along the second trench 285 in the non-display area NA on the upper, left, right, and lower sides of the display device 200, but is not limited thereto.

For example, outside the GIP circuit part 108, an outer bank 216′ and an inner bank 216″, which are separated from the bank 216 in an island shape, may be disposed.

For example, in the non-display area NA excluding the second side, the outer bank 216′ may cover an outer portion of the first low potential power line 235 in an island shape. Meanwhile, the outer bank 216′ and the inner bank 216″ may be separated and disposed on both sides with respect to the first trench 280, and a part of a top surface of the first low potential power line 235 may be exposed without being covered by the outer bank 216′.

The outer bank 216′ may be disposed at a predetermined distance from the edges of the adhesive layer 165 and the encapsulation substrate 160. That is, in the second embodiment of the present disclosure, the outer bank 216′ is formed to cover the tapered portions of the first low potential power line 235 and the planarization layer 215 outside the first trench 280, and is removed in the remaining areas.

For example, the inner bank 216″ may be disposed in an island shape to cover the inner portion of the first low potential power line 235 and/or the side portion of the second low potential power line 236. That is, the inner bank 216″ and the second low potential power line 236 may be provided in plurality: one inner bank 216″ may cover the inner portion of the first low potential power line 235 and the side portion of the second low potential power line 236, while another inner bank 216″ may cover the side portion of one second low potential power line 236 and the side portion of another second low potential power line 236.

In contrast, in the non-display area NA on the second side, the bank 216 may extend to the non-display area NA along the planarization layer 215, but is not limited thereto.

Meanwhile, in the non-display area NA, the organic layer 132 may be disposed on the bank 216.

The organic layer 132 extends to the non-display area NA, and its edge may be disposed inside compared to the edge of the bank 216, but is not limited thereto.

In the non-display area NA, the cathode 233 may be disposed on the organic layer 132.

In this case, the cathode 233 may extend into the first trench 280 to cover a part of the exposed top surface of the first low potential power line 235, but is not limited thereto.

For example, in the non-display area NA excluding the second side, the cathode 233 may extend into the first trench 280 to cover the inner bank 216″ and the second low potential power line 236. On the other hand, in the non-display area NA on the second side, the cathode 233 may extend to the non-display area NA to cover the inner bank 216″ and the second trench 285.

The cathode 233 may be in contact with the exposed top surface of the first low potential power line 235 to receive low potential power from the first low potential power line 235.

In addition, the protective layer 240 may extend into the trenches 280 and 285 to cover the cathode 233, but is not limited thereto. In this case, for example, the protective layer 240 may be disposed to surround the cathode 233 in the non-display area NA excluding the second side. In contrast, in the non-display area NA on the second side, the protective layer 240 may cover a part of the upper surface of the cathode 233 inside the second trench 285. In addition, the protective layer 240 may cover the inside of the second trench 285.

The encapsulation substrate 160 may be disposed over the protective layer 240 with an adhesive layer 165 interposed therebetween.

Meanwhile, the display device 200 according to the second exemplary embodiment of the present disclosure configured as described above is characterized in that the GIP circuit part 108 is disposed inside the second trench 285.

The second embodiment of the present disclosure is characterized in that the first trench 280 and the plurality of second trenches 285 are disposed at the edge of the non-display area NA, and the GIP circuit part 108 is disposed inside the second trench 285 so as to be spaced apart from the innermost second trench 285 at a predetermined interval G1.

As described above, in the second exemplary embodiment of the present disclosure, a plurality of second trenches 285 are additionally disposed in the first trench 280 to further delay the moisture penetration rate to the side surface of the display device 200. Further, in the second exemplary embodiment of the present disclosure, the GIP circuit part 108 is disposed inside the second trench 285 provided inside more than the first trench 280 to more effectively suppress the penetration of moisture or oxygen.

Meanwhile, according to the present disclosure, an encapsulation structure of a multilayer structure composed of a sealing member and a reinforcing substrate may be disposed on a cathode, and this will be described in detail with reference to the drawings.

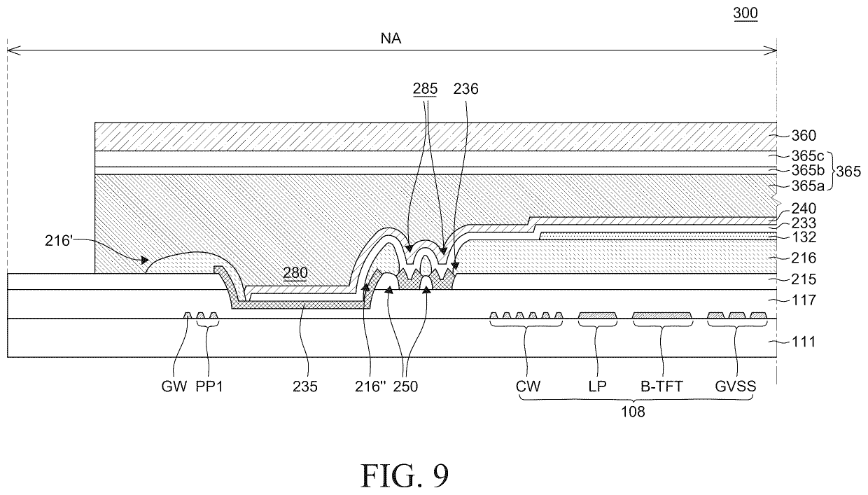

FIG. 9 is a cross-sectional view of a display device according to a third embodiment of the present disclosure.

The third embodiment of FIG. 9 is substantially the same as the second embodiment of FIGS. 6 to 8 described above except that the encapsulation structure of the multilayer structure composed of the sealing member 365 and the reinforcing substrate 360 is applied. Therefore, redundant description thereof will be omitted. In addition, the same reference numerals will be used for the same components. Hereinafter, description of the same reference numerals may refer to FIGS. 1 to 8.

FIG. 9 illustrates a part of the non-display area NA on the first side as an example in the display device 300 according to the third embodiment of the present disclosure.

Referring to FIG. 9, in the display device 300 according to the third embodiment of the present disclosure, a first trench 280 and a plurality of second trenches 285 may be disposed in the non-display area NA.

A plurality of dams 250 may be disposed between the second trenches 285.

A first low potential power line 235 may be disposed in the first trench 280.

In addition, a second low potential power line 236 may be disposed inside the second trench 285.

In the non-display area NA on the left and right sides of the third exemplary embodiment of the present disclosure, the GIP circuit part 108 may be disposed inside the second trench 285.

For example, outside the GIP circuit part 108, an outer bank 216′ and an inner bank 216″, which are separated from the bank 216 in an island shape, may be disposed.

Further, the cathode 233 may extend into the first trench 280 so as to cover a part of the exposed top surface of the first low potential power line 235. The cathode 233 may extend into the first trench 280 to cover the inner bank 216″ and the second low potential power line 236.

An encapsulation structure of a multilayer structure composed of a sealing member 365 and a reinforcing substrate 360 may be disposed over the cathode 233.

A small-sized display panel used in a mobile device and a portable device has a small area of the display panel so that heat generation in an element is rapidly emitted and there is less problem of bonding. However, in a large-sized display panel used in a monitor, tablet, or television receiver, the area of the display panel is large, so that an encapsulation structure for an optimal heat dissipation effect and bonding force is required.

In addition, in order to complement insufficient rigidity, the display device may further include a separate inner plate on the encapsulation substrate. In this case, it is necessary to secure a space for disposing a separate inner plate, and there is a problem in that there is a limitation in slimming and lightening of the display device due to the weight of the inner plate. In addition, there is a limitation in that a vertical space is generated by an air gap generated between the encapsulation substrate and the inner plate as much as the thickness of the adhesive tape disposed to adhere the encapsulation substrate and the inner plate, thereby deteriorating heat dissipation performance.

Accordingly, in the third embodiment of the present disclosure, it is possible to fix the reinforcing substrate 360 having a relatively large thickness while removing the separate inner plate, and it is characterized in that the encapsulation structure of the multilayer structure including the sealing member 365 which can prevent the process failure is applied.

For example, the sealing member 365 according to the third exemplary embodiment of the present disclosure may include a first adhesive layer 365a facing the substrate 111, a second adhesive layer 365c facing the reinforcing substrate 360, and a barrier layer 365b disposed between the first adhesive layer 365a and the second adhesive layer 365c.

In this case, each of the first adhesive layer 365a and the second adhesive layer 365c may be made of a polymer material having adhesiveness. For example, the first adhesive layer 365a may be made of any one of olefin-based, epoxy-based, and acrylate-based polymer materials. In addition, the second adhesive layer 365c may be made of any one of olefin-based, epoxy-based, acrylate-based, amine-based, phenol-based, and acid anhydride-based materials that do not contain a carboxyl group.

For heat dissipation of the substrate 111, at least the first adhesive layer 365a of the first and second adhesive layers 365a and 365c may be formed of a mixture including particles of an adhesive polymer material and a metal material. For example, the particles of the metal material may be powder made of nickel (Ni).

In this way, since the speed at which the driving heat generated in the substrate 111 is discharged through the sealing member 365 may be improved, the heat dissipation effect on the substrate 111 may be improved.

In addition, in order to prevent moisture permeation, the first adhesive layer 365a may be formed of a mixture further including a hygroscopic inorganic filler. The hygroscopic inorganic filler may be at least one of barium oxide (BaO), calcium oxide (CaO), and magnesium oxide (MgO).

In addition, since the first adhesive layer 365a and the second adhesive layer 365c are formed in a multi-layered structure, there is an advantage in that the reliability to reduce the warpage phenomenon in which the display panel is bent may also be improved.

The barrier layer 365b may be formed of any one of a metal material and an inorganic insulating material. That is, the barrier layer 365b may include a metal material such as Al, Cu, Sn, Ag, Fe, Zn and the like. In another example, the barrier layer 365b may be formed of a thin film of an inorganic insulating material such as SiOx and SiONx.

As described above, since the sealing member 365 of the third embodiment of the present disclosure includes the first and second adhesive layers 365a and 365c separated by the barrier layer 365b, it may be implemented to have a thickness about twice as thick as the adhesive material of the single layer without a process defect. Accordingly, since the reinforcing substrate 360 fixed by the sealing member 365 may be provided with a thick thickness, there is an advantage in that the increase in rigidity and the improvement of the heat dissipation effect may be easily realized.

For example, the reinforcing substrate 360 may be made of any one of glass, metal, and plastic polymers. For example, the reinforcing substrate 360 may be made of a metal material including components of Al, Cu, Sn, Ag, Fe, or Zn.

Meanwhile, the cathode of the present disclosure may be disposed to completely cover the inside of the trench, and this will be described in detail with reference to the drawings.

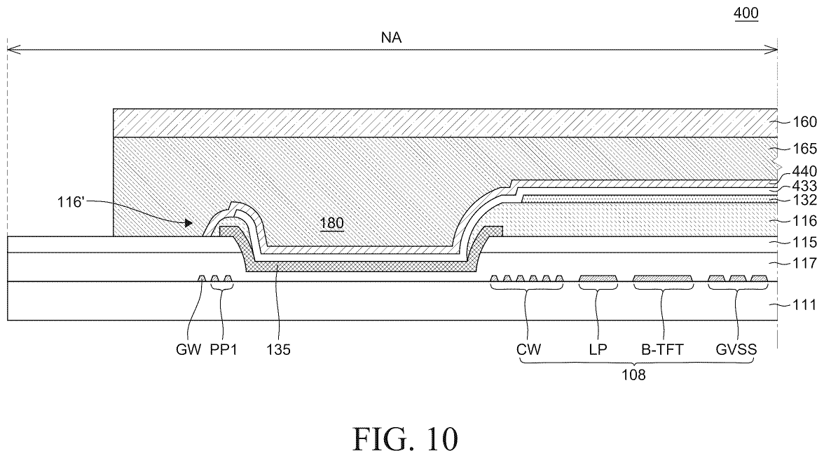

FIG. 10 is a cross-sectional view of a display device according to a fourth embodiment of the present disclosure.

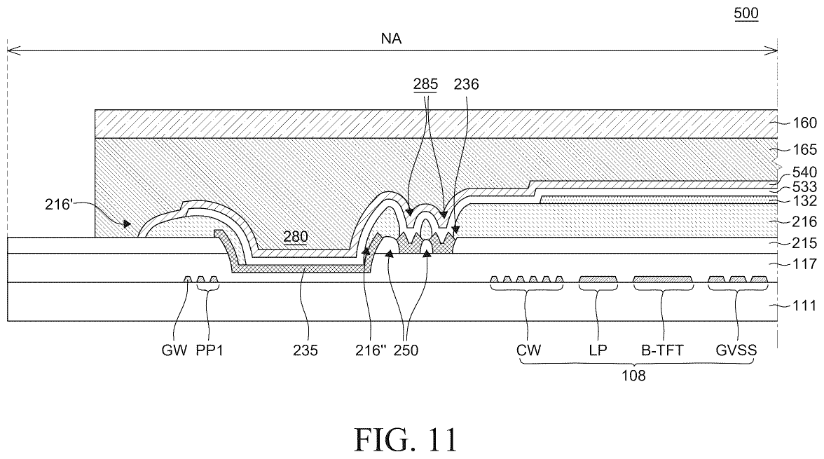

FIG. 11 is a cross-sectional view of a display device according to a fifth embodiment of the present disclosure.

The fourth embodiment of FIG. 10 is substantially the same as the first embodiment of FIGS. 1 to 5 described above excluding configurations of the cathode 433 and the protective layer 440, and accordingly, their common features are substantially the same, and therefore, redundant descriptions thereof will be omitted. Further, in the fifth embodiment of FIG. 11, only a configuration of the cathode 533 is different from that of the third embodiment of FIGS. 7 to 9 described above, and other configurations including the protective layer 540 are substantially the same, so that a redundant description will be omitted. The same components will be denoted by the same reference numerals. Hereinafter, description of the same reference numerals may refer to FIGS. 1 to 9.

FIGS. 10 and 11 illustrate a part of the non-display area NA on the first side as an example in the display devices 400 and 500 of the fourth and fifth embodiments of the present disclosure, respectively.

Referring to FIG. 10, a trench 180 may be provided at an edge of the non-display area NA between the substrate 111 and the encapsulation substrate 160.

In the non-display area NA on the left and right sides, the GIP circuit part 108 may be disposed inside the trench 180.

A low potential power line 135 may be disposed in the trench 180.

For example, the bank 116 may extend to the non-display area NA to cover an inner portion of the low potential power line 135. Meanwhile, the outer bank 116′separated from the bank 116 around the trench 180 may cover the outer portion of the low potential power line 135 in an island shape, and a part of the upper surface of the low potential power line 135 may be exposed without being covered by the outer bank 116′.

In the non-display area NA, the cathode 433 may be disposed on the organic layer 132.

The cathode 433 according to the fourth embodiment of the present disclosure may extend to the non-display area NA so as to cover the entire trench 180. That is, for example, the cathode 433 may extend to the non-display area NA so as to cover the side surface and a part of the upper surface of the outer bank 116′ on the upper and outer sides of the exposed low potential power line 135.

In addition, the protective layer 440 may extend to the non-display area NA to cover the cathode 433, but is not limited thereto. Further, for example, the protective layer 440 may extend to the non-display area NA to surround the cathode 433 and the outer bank 116′.

Referring to FIG. 11, in the non-display area NA on the left and right sides, the GIP circuit part 108 may be disposed inside the trenches 280 and 285. The GIP circuit part 108 may be disposed together on the first side and the second side facing the first side.

The trenches 280 and 285 may include a first trench 280 and a plurality of second trenches 285 sequentially disposed from the outside.

For example, a plurality of dams 250 may be disposed between the second trenches 285.

A first low potential power line 235 may be disposed in the first trench 280.

In addition, a second low potential power line 236 may be disposed inside the second trench 285.

For example, outside the GIP circuit part 108, an outer bank 216′ and an inner bank 216″, which are separated from the bank 216 in an island shape, may be disposed.

For example, the outer bank 216′ may cover an outer portion of the first low potential power line 235 in an island shape. In addition, the inner bank 216″ may cover the inner portion of the first low potential power line 235 and/or the side portion of the second low potential power line 236 in the form of an island.

In the non-display area NA, the cathode 533 may be disposed on the organic layer 132.

The cathode 533 according to the fifth embodiment of the present disclosure may extend to the non-display area NA so as to cover the entire trenches 280 and 285. For example, the cathode 533 may extend to the non-display area NA so as to cover the inner banks 216″ and the second low potential power line 236, including a top surface of the exposed low potential power line 235 and a side surface and a part of a top surface of the outer bank 216′. In addition, the protective layer 540 may extend to the non-display area NA to cover the cathode 533, but is not limited thereto. Further, for example, the protective layer 540 may extend to the non-display area NA to surround the cathode 533 and the outer bank 216′.

The exemplary embodiments of the present disclosure can also be described as follows:

A display device according to an exemplary embodiment of the present disclosure may include a substrate including a display area and a non-display area outside the display area, an insulating layer and a planarization layer disposed above the substrate and extending from the display area to the non-display area, at least one trench disposed in the non-display area and formed by removing a partial area of at least one of the insulating layer and the planarization layer, a bank disposed on the planarization layer and extending to the non-display area, an organic layer disposed on the bank, a cathode disposed on the organic layer and extending to the at least one trench, a protective layer disposed on the cathode, and a gate-in-panel (GIP) circuit part disposed in the non-display area on a first side and positioned inside the at least one trench.

A data pad part may be disposed on a second side adjacent to the first side on which the gate-in-panel circuit part is disposed.

The at least one trench may be disposed to surround the display area excluding the second side.

The display device may further include a ground wiring disposed over the substrate in the non-display area excluding the second side, a first light blocking pattern disposed inside the ground wiring and a link line disposed over the substrate in the non-display area on the second side.

The display device may further include a second light blocking pattern and a high potential power line which are disposed in the non-display area on a third side and/or a fourth side in which the gate-in-panel circuit part and the data pad part do not exist and positioned inside the at least one trench.

The display device may further include a first low potential power line disposed in the at least one trench so as to cover the inside of the at least one trench, the first low potential power line may cover a top surface of the insulating layer, and a part of a top surface and a side surface of the planarization layer exposed by the at least one trench.

The first low potential power line may include an inner portion and an outer portion disposed on an inclined side surface of the at least one trench, in the non-display area excluding the second side, the bank may extend to the non-display area so as to cover the inner portion of the first low potential power line and in the non-display area on the second side, the bank may extend to the non-display area along the planarization layer.

The display device may further include an outer bank which is separated from the bank with respect to the at least one trench and covers an outer portion of the first low potential power line in the form of an island, a part of a top surface of the first low potential power line may be exposed without being covered by the outer bank.

An encapsulation substrate may be disposed over the protective layer with an adhesive layer interposed therebetween and the outer bank may be disposed at a predetermined distance from edges of the adhesive layer and the encapsulation substrate.

The cathode may be extended into the at least one trench so as to cover a part of an upper surface of the exposed first low potential power line, the cathode may be in contact with the upper surface of the exposed first low potential power line, and the cathode may cover the bank and the organic layer inside the at least one trench.

In the non-display area excluding the second side, the protective layer may be disposed to surround the cathode, and in the non-display area on the second side, the protective layer may cover a part of an upper surface of the cathode.

The at least one trench may include a first trench disposed in the non-display area excluding the second side and a second trench positioned inside the first trench and disposed in the non-display area on the first side to the fourth side.

The first trench may be configured by removing partial areas of the insulating layer and the planarization layer of the non-display area and the second trench may be configured by removing a partial area of the planarization layer of the non-display area.

A plurality of second trenches may be disposed and the display device may further comprise a plurality of dams disposed between the plurality of second trenches and configured as the planarization layer.

The display device may further include a first low potential power line disposed in the first trench so as to cover the inside of the first trench, the first low potential power line may be disposed so as to cover a top surface of the insulating layer and a part of a top surface and a side surface of the planarization layer exposed by the first trench.

The display device may further include a second low potential power line disposed in the second trench so as to cover the inside of the second trench, the second low potential power line may be disposed so as to cover a top surface of the insulating layer and a part of a top surface and a side surface of the dam exposed by the second trench.

The display device may further include an outer bank and an inner bank which are separated from the bank and disposed in an island shape on an outside of the GIP circuit part, in the non-display area excluding the second side, the outer bank may cover an outer portion of the first low potential power line, and a part of the upper surface of the first low potential power line may be exposed without being covered by the outer bank.

An encapsulation substrate may be disposed over the protective layer with an adhesive layer interposed therebetween, and the outer bank may be disposed at a predetermined distance from edges of the adhesive layer and the encapsulation substrate.

The inner bank and the second low potential power line may be configured in plural, one of the inner banks may cover an inner side of the first low potential power line and a side of one of the second low potential power lines, and another one of the inner banks may cover the side of the one of the second low potential power line and a side of another one of the second low potential power line.

In the non-display area excluding the second side, the cathode may extend into the first trench to cover the inner bank and the second low potential power line, and in the non-display area on the second side, the cathode may extend to the non-display area to cover the inner bank and the second trench.

In the non-display area excluding the second side, the protective layer may be disposed to surround the cathode, and in the non-display area on the second side, the protective layer may cover a part of an upper surface of the cathode inside the second trench.

The cathode may extend to the non-display area to cover the entire at least one trench, and the protective layer may extend to the non-display area to surround the cathode.

The gate-in-panel circuit part may be disposed together on the first side and the second side facing the first side.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including a display area and a non-display area outside the display area;
an insulating layer and a planarization layer disposed on the substrate and extending from the display area to the non-display area;
at least one trench disposed in the non-display area and formed by removing a partial area of at least one of the insulating layer and the planarization layer;
a bank disposed on the planarization layer and extending to the non-display area;
an organic layer disposed on the bank;
a cathode disposed on the organic layer and extending to the at least one trench;
a protective layer disposed on the cathode; and
a gate-in-panel (GIP) circuit part disposed in the non-display area on a first side and positioned inside the at least one trench.

2. The display device according to claim 1, wherein a data pad part is disposed on a second side adjacent to the first side on which the gate-in-panel circuit part is disposed.

3. The display device according to claim 2, wherein the at least one trench is disposed to surround the display area excluding the second side.

4. The display device according to claim 2, further comprising:
a ground wiring disposed over the substrate in the non-display area excluding the second side;
a first light blocking pattern disposed inside the ground wiring; and
a link line disposed over the substrate in the non-display area on the second side.

5. The display device according to claim 4, further comprising:
a second light blocking pattern and a high potential power line which are disposed in the non-display area on a third side and/or a fourth side in which the gate-in-panel circuit part and the data pad part do not exist and positioned inside the at least one trench.

6. The display device according to claim 2, further comprising:
a first low potential power line disposed in the at least one trench so as to cover the inside of the at least one trench,
wherein the first low potential power line covers a top surface of the insulating layer, and a part of a top surface and a side surface of the planarization layer exposed by the at least one trench.

7. The display device according to claim 6, wherein the first low potential power line includes an inner portion and an outer portion disposed on an inclined side surface of the at least one trench,
wherein in the non-display area excluding the second side, the bank extends to the non-display area so as to cover the inner portion of the first low potential power line, and
wherein in the non-display area on the second side, the bank extends to the non-display area along the planarization layer.

8. The display device according to claim 7, further comprising:
an outer bank which is separated from the bank with respect to the at least one trench and covers the outer portion of the first low potential power line in the form of an island,
wherein a part of a top surface of the first low potential power line is exposed without being covered by the outer bank.

9. The display device according to claim 8, wherein an encapsulation substrate is disposed over the protective layer with an adhesive layer interposed therebetween, and
wherein the outer bank is disposed at a predetermined distance from edges of the adhesive layer and the encapsulation substrate.

10. The display device according to claim 8, wherein the cathode is extended into the at least one trench so as to cover a part of an upper surface of the exposed first low potential power line,
wherein the cathode is in contact with the upper surface of the exposed first low potential power line, and
wherein the cathode covers the bank and the organic layer inside the at least one trench.

11. The display device according to claim 2, wherein in the non-display area excluding the second side, the protective layer is disposed to surround the cathode, and
wherein in the non-display area on the second side, the protective layer covers a part of an upper surface of the cathode.

12. The display device according to claim 5, wherein the at least one trench includes:
a first trench disposed in the non-display area excluding the second side; and
a second trench positioned inside the first trench and disposed in the non-display area on the first side to the fourth side.

13. The display device according to claim 12, wherein the first trench is configured by removing partial areas of the insulating layer and the planarization layer of the non-display area, and
wherein the second trench is configured by removing a partial area of the planarization layer of the non-display area.

14. The display device according to claim 13, wherein a plurality of second trenches are disposed, and
wherein the display device further comprises a plurality of dams disposed between the plurality of second trenches and configured as the planarization layer.

15. The display device according to claim 12, further comprising:
a first low potential power line disposed in the first trench so as to cover the inside of the first trench,
wherein the first low potential power line is disposed so as to cover a top surface of the insulating layer and a part of a top surface and a side surface of the planarization layer exposed by the first trench.

16. The display device according to claim 15, further comprising:
a second low potential power line disposed in the second trench so as to cover the inside of the second trench,
wherein the second low potential power line is disposed so as to cover a top surface of the insulating layer and a part of a top surface and a side surface of the dam exposed by the second trench.

17. The display device according to claim 16, further comprising:
an outer bank and an inner bank which are separated from the bank and disposed in an island shape on an outside of the GIP circuit part,
wherein in the non-display area excluding the second side, the outer bank covers an outer portion of the first low potential power line, and
wherein a part of the upper surface of the first low potential power line is exposed without being covered by the outer bank.

18. The display device according to claim 17, wherein an encapsulation substrate is disposed over the protective layer with an adhesive layer interposed therebetween, and
wherein the outer bank is disposed at a predetermined distance from edges of the adhesive layer and the encapsulation substrate.

19. The display device according to claim 17, wherein the inner bank and the second low potential power line are configured in plural,
wherein one of the inner banks covers an inner side of the first low potential power line and a side of one of the second low potential power lines, and
wherein another one of the inner banks covers the side of the one of the second low potential power line and a side of another one of the second low potential power line.

20. The display device according to claim 17, wherein in the non-display area excluding the second side, the cathode extends into the first trench to cover the inner bank and the second low potential power line, and
wherein in the non-display area on the second side, the cathode extends to the non-display area to cover the inner bank and the second trench.

21. The display device according to claim 17, wherein in the non-display area excluding the second side, the protective layer is disposed to surround the cathode, and
wherein in the non-display area on the second side, the protective layer covers a part of an upper surface of the cathode inside the second trench.

22. The display device according to claim 1, wherein the cathode extends to the non-display area to cover the entire at least one trench, and
wherein the protective layer extends to the non-display area to surround the cathode.

23. The display device according to claim 1, wherein the gate-in-panel circuit part is disposed together on the first side and the second side facing the first side.

24. A display device, comprising:
a substrate including a display area and a non-display area outside the display area;
at least one trench disposed in the non-display area;
a first low potential power line disposed in the trench;
a cathode disposed in the display area so as to extend to the at least one trench and coupled to the first low potential power line;
a gate-in-panel circuit part disposed in the non-display area on a first side and positioned inside the at least one trench; and
a ground wiring disposed outside the at least one trench in the non-display area on the first side and a third side.

25. The display device according to claim 24, wherein the at least one trench includes:
a first trench disposed in the non-display area; and
one or more second trenches disposed in the non-display area on the first side, a second side, the third side and a fourth side.

26. The display device according to claim 24, further comprising:
a first light blocking pattern disposed between the ground wiring and the at least one trench.

27. The display device according to claim 24, further comprising:
a second light blocking pattern and a high potential power line disposed on an inner side of the at least one trench.

28. The display device according to claim 25, further comprising:
one or more second low potential power lines disposed inside the one or more second trenches and coupled to the cathode.

29. The display device according to claim 25, wherein the first trench has a width greater than that of each of the one or more second trenches.

30. The display device according to claim 25, further comprising:
a plurality of dams disposed between the one or more second trenches.
